(19) United States
(12) Patent Application Publication
(10) Pub. No.: US 2026/0011544 A1
(43) Pub. Date: Jan. 8, 2026

(54) SUBSTRATE PROCESSING APPARATUS AND SUBSTRATE PROCESSING METHOD

(71) Applicant: Tokyo Electron Limited, Tokyo (JP)

(72) Inventors: Ryohei YONEDA, Yamanashi (JP); Tatsuya YAMAGUCHI, Yamanashi (JP)

(73) Assignee: Tokyo Electron Limited, Tokyo (JP)

(21) Appl. No.: 19/241,752

(22) Filed: Jun. 18, 2025

(30) Foreign Application Priority Data
Jul. 4, 2024 (JP) 2024-108251

(51) Int. Cl. H01L 21/02; H01L 21/67

(52) U.S. Cl. CPC H01L 21/02087; H01L 21/67069

(57) ABSTRACT

A substrate processing apparatus cleans a substrate. The substrate processing apparatus includes a processing container, a stage, a top board, a lifting/lowering mechanism, and a guide mechanism. The stage is located inside the processing container and configured to support the substrate. The top board faces the stage. The lifting/lowering mechanism is configured to lift and lower the substrate. The guide mechanism is located on the top board and configured to bring the substrate into contact therewith.

### CROSS-REFERENCE TO RELATED APPLICATION

This application claims the benefit of priority of the prior Japanese Patent Application No. 2024-108251, filed on Jul. 4, 2024, the entire contents of which are incorporated herein by reference.

### FIELD

Exemplary embodiments disclosed herein relate to a substrate processing apparatus and a substrate processing method.

### BACKGROUND

For example, a bevel etcher with a gap control function has been developed in Japanese Patent No. 5248526. The Japanese Patent No. 5248526 discloses a “bevel etcher for plasma cleaning a semiconductor substrate comprises a lower electrode assembly having a top surface and adapted to support a substrate having a bevel edge, an upper electrode assembly including a bottom surface that opposes and is in a spaced-apart relationship with the top surface to form a gap for receiving the substrate therein, the lower and upper electrode assemblies being operative to generate plasma for cleaning the bevel edge during operation, and at least one mechanism supporting the upper electrode assembly and adapted to adjust the tilt angle and horizontal translation of the bottom surface relative to the top surface”.

The present disclosure provides a substrate processing apparatus and a substrate processing method that can narrow the distance between a substrate and a top board.

### SUMMARY

According to an aspect of an embodiment, a

substrate processing apparatus cleans a substrate. The substrate processing apparatus includes a processing container, a stage, a top board, a lifting/lowering mechanism, and a guide mechanism. The stage is located inside the processing container and configured to support the substrate. The top board faces the stage. The lifting/lowering mechanism is configured to lift and lower the substrate. The guide mechanism is located on the top board and configured to bring the substrate into contact therewith.

### BRIEF DESCRIPTION OF DRAWINGS

FIG. 1 is a schematic sectional view of the configuration of a substrate processing apparatus according to an embodiment;

FIG. 2 is a sectional view of a guide mechanism cut along a line A-A in FIG. 1;

FIG. 3A is an enlarged view of the outer peripheral part of a substrate and the periphery thereof during heating;

FIG. 3B is an enlarged view of the outer peripheral part of the substrate and the periphery thereof during cleaning;

FIG. 4 is a schematic sectional view of another configuration of the substrate processing apparatus according to the embodiment; and

FIG. 5 is a flowchart illustrating an example of a substrate processing method according to the embodiment.

### DESCRIPTION OF EMBODIMENTS

Hereinafter, an exemplary embodiment of a substrate processing apparatus and a substrate processing method according to the disclosure will be described in detail with reference to the accompanying drawings. However, the substrate processing apparatus and the substrate processing method according to the present disclosure is not limited to the embodiment. The following embodiments may be appropriately combined within a range that does not contradict the configurations and processing contents of the present disclosure.

Moreover, in the embodiments described below, expressions such as “constant”, “orthogonal”, “vertical”, or “parallel” may be used. However, these expressions do not need to be exactly “constant”, “orthogonal”, “vertical”, or “parallel”. That is, for example, each of the above expressions allows deviations in manufacturing accuracy, installation accuracy, and the like. Furthermore, each of the drawings referred to below is a schematic drawing for the sake of explanation. Therefore, details may be omitted, and the dimensional ratios do not always match the actual ones.

### Configuration of Substrate Processing Apparatus

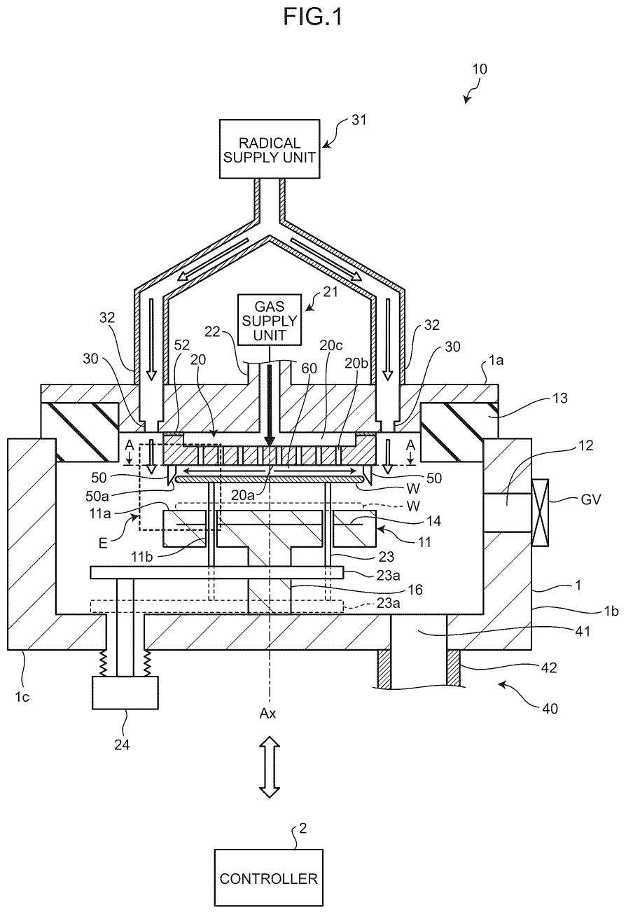

An example of the configuration of a substrate processing apparatus according to an embodiment will be described with reference to FIG. 1. FIG. 1 is a schematic sectional view of the configuration of a substrate processing apparatus according to an embodiment. A substrate processing apparatus 10 is an example of an apparatus that cleans a substrate with radicals of etching gas.

In the description of the following embodiment, a substrate W, an example of which is a semiconductor wafer, may be described by dividing the substrate W into a center part around a central axis Ax of the substrate W, and an outer peripheral part located outside the center part. In the present specification, the outer peripheral part of the substrate W includes a front surface of the substrate W outside the center part of the substrate W, a rear surface of the substrate W outside the center part of the substrate W, and an outer peripheral end part of the substrate W. For example, the outer peripheral part of the substrate W may be within a range about 10 mm to about 100 mm from the outer peripheral end part of the substrate W in the radial direction of the substrate W. Cleaning the outer peripheral part of the substrate W means to remove a film adhering to the front surface of the substrate W, the rear surface of the substrate W, and the outer peripheral end part of the substrate W within the range described above that configures the outer peripheral part of the substrate W. The substrate processing apparatus 10 is an example of a bevel etching apparatus that cleans the outer peripheral part of the substrate W.

The substrate processing apparatus 10 includes a processing container 1 and a controller 2. The processing container 1 is formed in a cylindrical shape around the central axis Ax. For example, the processing container 1 is made of aluminum alloy and is electrically grounded.

The inner wall surface of the processing container 1 is coated with an alumina (Al₂O₃) film or an yttrium oxide (Y₂O₃) film.

The processing container 1 includes a side part 1b and a bottom part 1c. A loading/unloading port 12 of the substrate W is provided on the side part 1b. The substrate processing apparatus 10 is connected to the outside via the loading/unloading port 12. The loading/unloading port 12 is opened and closed by a gate valve GV. The bottom part 1c is located below the side part 1b, and the side part 1b and the bottom part 1c are integrally formed.

Furthermore, the processing container 1 includes a lid part 1a. The lid part 1a is located above the side part 1b via a ring member 13 serving as an insulator, and is electrically insulated from the side part 1b. The inner space of the processing container 1 is defined by the lid part 1a, the side part 1b, and the bottom part 1c.

The processing container 1 accommodates the substrate W. A stage 11 is located inside the processing container 1. The stage 11 includes a substrate supporting surface 11a, and horizontally supports the substrate W with the substrate supporting surface 11a. The stage 11 is supported by a support member 16.

The central axis of the stage 11 coincides with the central axis Ax. In the present embodiment, the diameter of the substrate supporting surface 11a is larger than the diameter of the substrate W. A heater 14 for heating the substrate W is built in the stage 11.

Three (only two are illustrated in FIG. 1) support pins 23 are provided in the processing container 1 so as to protrude upward from a lifting/lowering plate 23a. A lifting/lowering mechanism 24 is connected to the support pin 23 via the lifting/lowering plate 23a. The lifting/lowering mechanism 24 is an example of a mechanism that lifts and lowers a substrate. For example, the lifting/lowering mechanism 24 is a motor. However, the lifting/lowering mechanism 24 is not limited to the motor, and may be any mechanism capable of generating driving force for lifting and lowering the support pin 23. A plurality (for example, three) of through holes 11b that penetrate through the stage 11 in the thickness direction are formed on the stage 11. The support pin 23 can be lifted and lowered by the lifting/lowering mechanism 24 via the lifting/lowering plate 23a, and can be protruded and retracted from the substrate supporting surface 11a by being inserted into one of the through holes 11b. The substrate W is raised from the substrate supporting surface 11a when the support pin 23 is lifted, and comes into contact with a guide mechanism 50.

A top board 20 is disposed above the stage 11, and is supported by the lid part 1a. The top board 20 is formed in a disk shape, and the central axis of the top board 20 coincides with the central axis Ax. The top board 20 may be formed of a plasma-resistant material such as alumina (Al₂O₃) or quartz. The top board 20 includes a facing surface 20a that faces the stage 11. The facing surface 20a is the lower surface of the top board 20. The diameter of the facing surface 20a is larger than the diameter of the substrate W. The diameter of the facing surface 20a is approximately equivalent to the diameter of the substrate supporting surface 11a. The top board 20 includes a plurality of gas holes 20b and a diffusion chamber 20c. The gas holes 20b are located inside a radical supply port 30, which will be described below, and penetrate through the facing surface 20a. The diffusion chamber 20c is located above the gas holes 20b, and communicates with the gas holes 20b. The diffusion chamber 20c is defined by a recess formed above the top board 20, and the lower surface of the lid part 1a.

A gas supply pipe 22 penetrates through the center of the lid part 1a, and communicates with the diffusion chamber 20c. Moreover, the gas supply pipe 22 is connected to a gas supply unit 21 outside the processing container 1. The gas supplied from the gas supply unit 21 flows through the gas supply pipe 22, diffuses in the diffusion chamber 20c, and is supplied to a gap 60 between the substrate W and the top board 20 from the gas holes 20b. The top board 20 having such a configuration functions as a gas shower head.

The processing container 1 includes a radical supply port 30 on the lid part 1a. The radical supply port 30 is an opening that penetrates through the lid part 1a in the thickness direction. A plurality of the radical supply ports 30 are concentrically arranged around the central axis Ax. A radical supply unit 31 is connected to a plurality of radical supply pipes 32 that extend and branch in a radial pattern. The radical supply pipes 32 are connected to a plurality of the radical supply ports 30. The radical supply unit 31 supplies radicals of etching gas to the outer peripheral part of the substrate W in the processing container 1 from the radical supply ports 30. The radical supply ports 30 irradiate the facing surface 20a with radicals in the vertical direction, and supplies radicals of etching gas to the outer peripheral part of the substrate W. However, it is not limited thereto, and the radical supply ports 30 may irradiate the facing surface 20a with radicals in the oblique direction or the parallel direction, and supply radicals of etching gas to the outer peripheral part of the substrate W. Consequently, the outer peripheral part of the substrate W is cleaned by the radicals of etching gas.

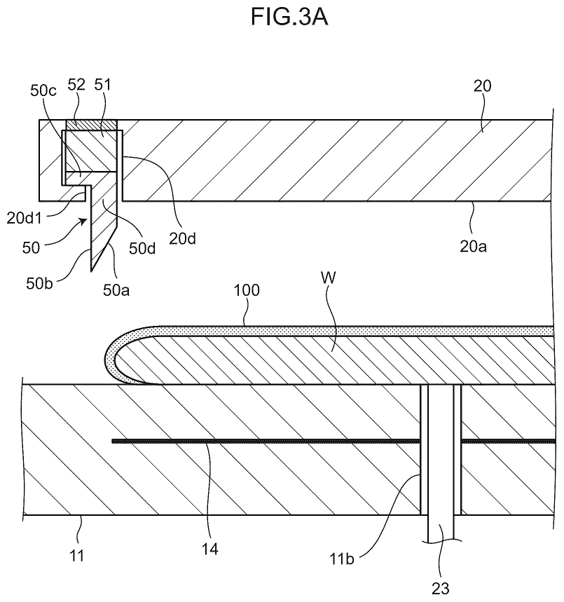

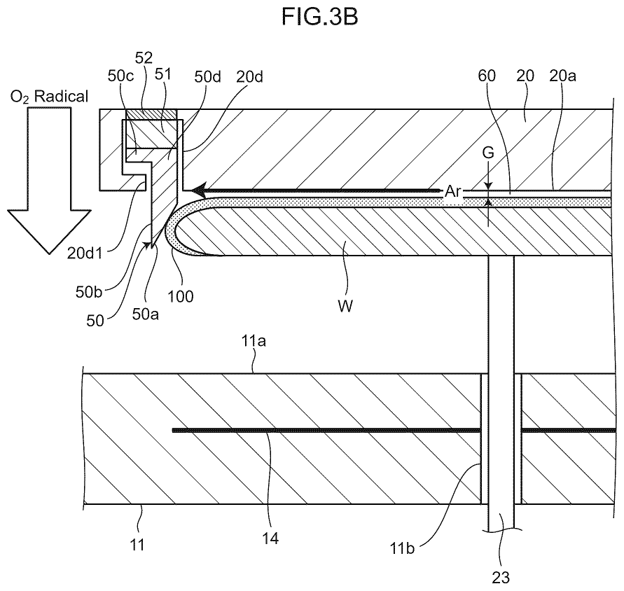

For example, a film 100 (see FIG. 3A and FIG. 3B) such as a polymer organic film is formed in advance on the substrate W to be conveyed. The film 100 is formed on the center part of the substrate W. However, the film 100 may also be formed on the outer peripheral part of the substrate W. Therefore, the substrate processing apparatus 10 removes the film 100 on the outer peripheral part of the substrate W with radicals of etching gas. For example, the radical supply unit 31 uses oxygen gas as the etching gas, and supplies radicals of oxygen gas. However, the etching gas is not limited thereto, and may also be ClF₃ gas. In this case, the radical supply unit 31 supplies radicals of ClF₃ gas. The radical supply unit 31 is a remote plasma source. The radical supply unit 31 may supply radicals of etching gas and argon gas.

The radical supply port 30 is located outside the top board 20 around the central axis Ax. The gas holes 20b are located inside the radical supply port 30. The gas supply unit 21 supplies argon gas through the gas holes 20b. The argon gas flows through the gap 60 between the top board 20 and the substrate W, from the center part of the substrate W toward the outer peripheral part. Due to the flow of the argon gas, the radicals of etching gas are prevented from flowing into the center part from the outer peripheral part of the substrate W. Consequently, it is possible to prevent the film 100 formed on the center part of the substrate W from being peeled off by the radicals of etching gas. The gas supplied by the gas supply unit 21 is not limited to argon gas, and may also be any inert gas other than argon gas.

The guide mechanism 50 is located on the top board 20, and configured to bring the substrate W into contact therewith. Consequently, the guide mechanism 50 adjusts the distance between the front surface of the substrate W and the facing surface 20a of the top board 20. The distance between the front surface of the substrate W and the facing surface 20a of the top board 20 is the distance of the gap 60 between the substrate W and the top board 20 in the vertical direction.

The guide mechanism 50 protrudes from the top board 20, and includes a contact surface 50a that comes into contact with the substrate W. The contact surface 50a may be a tapered surface at the tip end of the guide mechanism 50 protruding from the top board 20. The contact surface 50a is inclined obliquely with respect to the facing surface 20a. For example, the contact surface 50a may be inclined so that the contact surface 50a is tapered to the tip end of the guide mechanism 50 protruding from the top board 20.

The substrate processing apparatus 10 further includes an exhaust system 40. The exhaust system 40 includes an exhaust port 41 and an exhaust pipe 42. The exhaust port 41 is provided on the bottom part 1c of the processing container 1. The exhaust pipe 42 is connected to the exhaust port 41. The exhaust pipe 42 is connected to an exhaust device, which is not illustrated. The exhaust device includes a pressure regulating valve and a vacuum pump. The pressure in the processing container 1 is regulated by the pressure regulating valve. The vacuum pump includes a turbomolecular pump, a dry pump, or a combination of the turbomolecular pump and the dry pump.

The controller 2 processes computer-executable instructions that cause the substrate processing apparatus 10 to perform various processes described in the present disclosure. The controller 2 may control each element of the substrate processing apparatus 10 to perform various processes described herein. In the embodiment, part or all of the controller 2 may be included in the substrate processing apparatus 10. The controller 2 may include a processing unit, a storage, and a communication interface. For example, the controller 2 is implemented by a computer. The processing unit can perform various control operations, by reading a computer program from the storage, and executing the read computer program. The computer program may be stored in the storage in advance, or may be acquired via a medium when necessary. The acquired computer program is stored in the storage, and read from the storage by the processing unit for execution. The medium may be various computer-readable storage media or a communication line connected to the communication interface. The processing unit may be a central processing unit (CPU). The storage may include a random access memory (RAM), a read only memory (ROM), a hard disk drive (HDD), a solid state drive (SSD), or a combination of the above. The communication interface may communicate with the substrate processing apparatus 10 via a communication line such as a local area network (LAN).

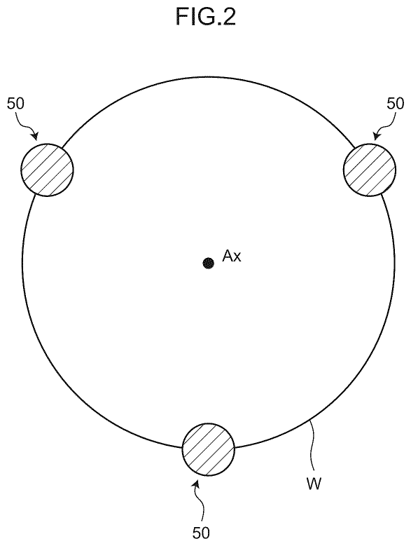

Referring to FIG. 1, FIG. 2, FIG. 3A, and FIG. 3B, the explanation of the configuration of the substrate processing apparatus 10 will be further continued. FIG. 2 is a sectional view of a guide mechanism cut along a line A-A in FIG. 1. FIG. 3A is an enlarged view of the outer peripheral part of the substrate W and the periphery thereof during heating. FIG. 3B is an enlarged view of the outer peripheral part of the substrate and the periphery thereof during cleaning. FIG. 3B is an enlarged view of a dotted frame E in FIG. 1.

As illustrated in FIG. 2, a plurality of the guide mechanisms 50 may be arranged at positions corresponding to the outer peripheral part of the substrate W in the peripheral direction, along the outer peripheral part of the substrate W. In the illustration, three guide mechanisms 50 are arranged at equal intervals in the peripheral direction. By setting the contact point of the substrate W to the guide mechanism 50 to three points, the substrate processing apparatus 10 can reduce the effects of particle generation, caused by contact between the guide mechanism 50 and the substrate W. Moreover, the guide mechanism 50 is provided on a part of the outer peripheral part of the substrate W, and is not arranged over the whole periphery. Consequently, the substrate processing apparatus 10 can exhaust the argon gas supplied from the gas holes 20b to the outer peripheral part of the substrate W from the gap 60 at a portion where the guide mechanism 50 is not arranged.

However, the number of guide mechanisms 50 is not limited to three, and may be two or four or more. The number of guide mechanisms 50 may also be one. The guide mechanisms 50 need not be arranged at equal intervals in the peripheral direction. Moreover, the guide mechanism 50 need not be arranged at equal intervals from the central axis Ax in the radial direction.

The guide mechanism 50 is a protrusion, and protrudes from the top board 20. In the examples in FIG. 3A and FIG. 3B, the top board 20 includes a recess part 20d at a position corresponding to the outer peripheral part of the substrate W. The recess part 20d is opened on the facing surface 20a. The guide mechanism 50 protrudes from the opening toward the outer peripheral part of the substrate W. The opening is narrowed by an engagement part 20d1, and the width of the opening is smaller than the width of the recess part 20d formed above. In a sectional view, the guide mechanism 50 is formed in an L-shape, and includes a base end part 50c that is accommodated in the recess part 20d and that engages with the engagement part 20d1.

Moreover, the guide mechanism 50 includes a protrusion part 50d that extends vertically from the base end part 50c, and protrudes from the top board 20 through an opening of the recess part 20d. A vertical surface 50b and the contact surface 50a are the surfaces located at the tip end of the protrusion part 50d of the guide mechanism 50. The vertical surface 50b located outside is orthogonal to the facing surface 20a, and the contact surface 50a located inside is inclined with respect to the facing surface 20a. Specifically, in a sectional view, the contact surface 50a is inclined so that the width between the vertical surface 50b and the contact surface 50a is reduced toward the tip end of the guide mechanism 50. The contact surfaces 50a of the three guide mechanisms 50 are inclined at the same angle.

Moreover, the substrate processing apparatus 10 includes a buffer member 51 that is located between the top board 20 and the guide mechanism 50, and that buffers the impact (contact force) caused by contact between the substrate W and the guide mechanism 50. The buffer member 51 is accommodated inside the recess part 20d, and is interposed between the base end part 50c of the guide mechanism 50 and the upper inner wall of the recess part 20d.

The guide mechanism 50 may also be formed of a plasma-resistant material such as alumina (Al₂O₃) or quartz (SiO₂). The guide mechanism 50 may be formed of the same material as the top board 20. The buffer member 51 may be formed of stainless steel or aluminum. The buffer member 51 may also be an elastic member such as a spring or a rubber. However, the buffer member 51 is not limited to the spring or rubber, and may be formed of a material with rigidity and elasticity that can buffer the impact caused by contact between the substrate W and the guide mechanism 50.

In the present embodiment, the guide mechanism 50 can move up and down by the expansion and contraction of the buffer member 51. However, the installation method of the guide mechanism 50 is not limited to the method illustrated in FIG. 3A and FIG. 3B. For example, the recess part 20d may be opened on the side surface of the top board 20. The guide mechanism 50 may be suspended downward from the opening on the side surface of the top board 20. Moreover, the guide mechanism 50 may be fixed to the top board 20 so as not to move.

In FIG. 3A, the substrate W is supported by the substrate supporting surface 11a of the stage 11. The heater 14 generates heat when power is supplied from a heater power supply (not illustrated). Then, the controller 2 controls the substrate W to a predetermined temperature, by controlling the output of the heater 14.

After adjusting the substrate W to a predetermined temperature by controlling the heater 14, in FIG. 3B, the controller 2 raises the support pin 23 to a predetermined position, by controlling the lifting/lowering mechanism 24 (see FIG. 1). Consequently, the substrate W is raised from the substrate supporting surface 11a of the stage 11, and comes into contact with the guide mechanism 50. As a control method for bringing the substrate W into contact with the guide mechanism 50, the controller 2 may measure in advance the height of the support pin 23 where the outer peripheral part of the substrate W comes into contact with the contact surface 50a of the guide mechanism 50, store the height in the storage, and control the support pin 23 to have the height stored in the storage. Consequently, as illustrated in FIG. 3B, the controller 2 brings the outer peripheral part of the substrate W into contact with the contact surface 50a of the guide mechanism 50. The outer peripheral part of the substrate W may be brought into surface contact, line contact, or point contact with the contact surface 50a of the guide mechanism 50. Consequently, by using the guide mechanism 50, the substrate processing apparatus 10 can narrow distance G between the front surface of the substrate W and the facing surface of the top board 20 to less than 0.5 mm. Moreover, by bringing the outer peripheral part of the substrate W into contact with a plurality of the contact surfaces 50a, it is possible to position the substrate W to a predetermined position.

### Other Configuration of Substrate Processing Apparatus

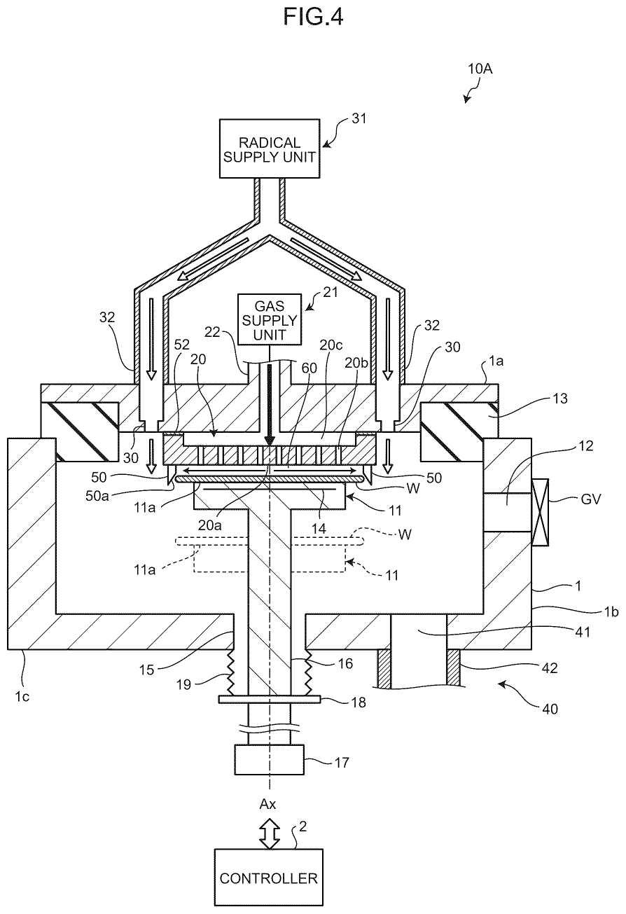

An example of the configuration of a substrate processing apparatus according to an embodiment will be described with reference to FIG. 4. FIG. 4 is a schematic sectional view of another configuration of the substrate processing apparatus according to the embodiment. A substrate processing apparatus 10A is an example of an apparatus that cleans the substrate W with radicals of etching gas.

The configuration of the lifting/lowering mechanism of the substrate processing apparatus 10A is different from that of the substrate processing apparatus 10 illustrated in FIG. 1. However, other configurations are the same. Thus, in the following, a lifting/lowering mechanism 17 of the substrate processing apparatus 10A is mainly explained, and explanation of other configurations will be omitted.

The support member 16 penetrates through an opening 15 formed on the bottom part 1c of the processing container 1 from the center of the bottom surface of the stage 11, extends below the processing container 1, and is connected to the lifting/lowering mechanism 17. The stage 11 can be lifted and lowered by the lifting/lowering mechanism 17 via the support member 16, between the processing position illustrated by the solid line in FIG. 4, and the conveyance position therebelow illustrated by the broken line where the substrate W can be conveyed. The lifting/lowering mechanism 17 is an example of a mechanism that lifts and lowers a substrate. For example, the lifting/lowering mechanism 17 is a motor. However, the lifting/lowering mechanism 17 is not limited to the motor, and may be any mechanism capable of generating driving force for lifting and lowering the stage 11. When the lifting/lowering mechanism 17 lifts the stage 11, the substrate W is raised to a position where the substrate W comes into contact with the guide mechanism 50. Consequently, the guide mechanism 50 adjusts the distance between the front surface of the substrate W and the facing surface 20a.

A flange part 18 is installed below the processing container 1 of the support member 16. Bellows 19 that defines the atmosphere in the processing container 1 from the outer air, and that expands and contracts with the lifting and lowering operation of the stage 11, is located between the bottom part 1c of the processing container 1 and the flange part 18.

In the present embodiment, the diameter of the substrate supporting surface 11a is smaller than the diameter of the facing surface 20a of the top board 20. Moreover, the diameter of the substrate supporting surface 11a is smaller than the diameter of the substrate W. Thus, the outer peripheral part of the substrate W protrudes from the side surface of the stage 11, and the front surface and the rear surface of the outer peripheral part of the substrate W are exposed to the outside of the stage 11. Thus, the radical supply unit 31 can clean the outer peripheral part of the substrate W, without raising the substrate W from the stage 11 using the support pins 23 and the like, by emitting radicals of etching gas from the radical supply ports 30.

After adjusting the substrate W to a predetermined temperature by controlling the heater 14, the controller 2 raises the stage 11 to a predetermined position, by controlling the lifting/lowering mechanism 17. Consequently, the substrate W comes into contact with the guide mechanism 50 while the substrate W is supported on the stage 11. As a control method for bringing the substrate W into contact with the guide mechanism 50, the controller 2 may also measure in advance the height of the stage 11 where the outer peripheral part of the substrate W comes into contact with the contact surface 50a of the guide mechanism 50, store the height in the storage, and control the stage 11 to have the height stored in the storage. Consequently, the controller 2 brings the outer peripheral part of the substrate W into contact with the contact surface 50a of the guide mechanism 50. The outer peripheral part of the substrate W may be brought into surface contact, line contact, or point contact with the contact surface 50a of the guide mechanism 50. Consequently, by using the guide mechanism 50, the substrate processing apparatus 10 can narrow the distance between the front surface of the substrate W and the facing surface of the top board 20 to less than 0.5 mm. Moreover, by bringing the outer peripheral part of the substrate W into contact with a plurality of the contact surfaces 50a, it is possible to position the substrate W to a predetermined position.

### Substrate Processing Method

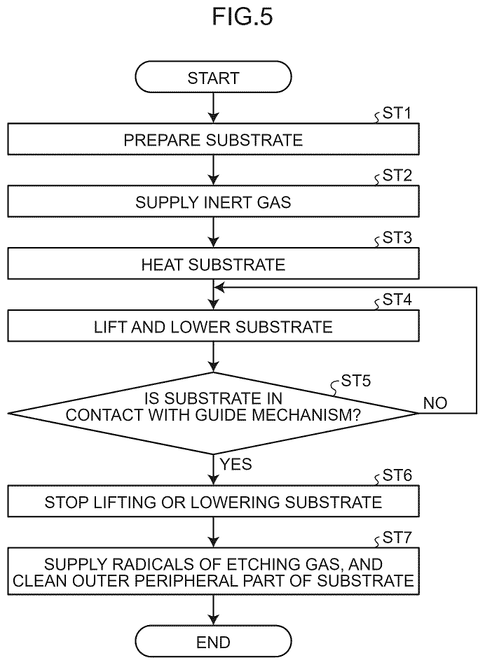

Next, a substrate processing method according to the embodiment will be described with reference to FIG. 5. FIG. 5 is a flowchart illustrating an example of a substrate processing method according to the embodiment. The substrate processing method according to the embodiment may be implemented by the substrate processing apparatus 10 or the substrate processing apparatus 10A. Each part of the substrate processing apparatus 10 or the substrate processing apparatus 10A may be controlled by the controller 2. In the following example, the controller 2 controls the cleaning of the outer peripheral part of the substrate W with the film 100 such as an organic film, by using the substrate processing apparatus 10.

### ST1: Prepare Substrate

First, at step ST1, the controller 2 performs a process of preparing the substrate W on the substrate supporting surface 11a. For example, the controller 2 opens the gate valve GV, and controls a transfer device, which is not illustrated, to convey the substrate W into the processing container 1 through the loading/unloading port 12, and to deliver the substrate W to the support pin 23. Then, the controller 2 controls the support pin 23 to be lowered, and the substrate W is supported on the substrate supporting surface 11a. It is to be noted that the step ST1 is an example of a process (A).

### ST2: Supply Inert Gas

Next, at step ST2, the controller 2 performs a process of supplying inert gas. For example, the controller 2 supplies inert gas to the gap 60 from the gas supply unit 21 through the gas holes 20b of the top board 20. The inert gas flows from the center part of the substrate W toward the outer peripheral part of the substrate W. Consequently, the controller 2 controls to prevent the radicals of etching gas supplied from the radical supply port 30 from flowing into the center part of the substrate W. For example, the controller 2 supplies argon gas as the inert gas. It is to be noted that the step ST2 is an example of a process (B).

### ST3: Heat Substrate

Next, at step ST3, the controller 2 performs a process of heating the substrate W on the substrate supporting surface 11a. For example, the controller 2 causes the heater 14 to generate heat by supplying power from a power supply, which is not illustrated, and heats the substrate W on the substrate supporting surface 11a to a predetermined temperature.

### ST4: Lift and Lower Substrate

Next, at step ST4, the controller 2 uses the lifting/lowering mechanism 24 to lift and lower the substrate W. In this example, the controller 2 raises the support pin 23 and brings the substrate W close to the facing surface 20a of the top board 20. For example, the controller 2 may control the support pin 23 to be raised to the height set in advance. In this process, the height of the support pin 23 set in advance corresponds to the position where the outer peripheral part of the substrate W comes into contact with the contact surface 50a of the guide mechanism 50. Consequently, the controller 2 controls the outer peripheral part of the substrate W to come into contact with the guide mechanism 50. It is to be noted that the step ST4 is an example of a process (C).

### ST5: Determine Contact

Next, at step ST5, the controller 2 determines whether the substrate W is in contact with the guide mechanism 50. When the controller 2 determines that the substrate W is not in contact with the guide mechanism 50, the process returns to step ST4, and the controller 2 controls the lifting and lowering of the substrate W, by lifting and lowering the support pin 23 using the lifting/lowering mechanism 24. When the controller 2 determines that the substrate W is in contact with the guide mechanism 50, the process proceeds to step ST6. It is to be noted that the step ST5 is an example of a process (D).

### ST6: Stop Lifting or Lowering Substrate

If the controller 2 determines that the substrate W is in contact with the guide mechanism 50 at step ST5, the controller 2 stops lifting or lowering the substrate W at step ST6. It is to be noted that the step ST6 is an example of a process (E).

### ST7: Clean Substrate

Next, at step ST7, the controller 2 performs a process of cleaning the outer peripheral part of the substrate W. For example, the controller 2 controls to irradiate radicals of etching gas from the radical supply port 30. Consequently, the film 100 on the outer peripheral part of the substrate W is etched, and the outer peripheral part of the substrate W is cleaned. For example, the controller 2 supplies plasma radicals generated from oxygen gas, as the radicals of etching gas. It is to be noted that the step ST7 is an example of a process (F).

An example of the controller 2 performing the processes at steps ST1 to ST7 in this order has been described. However, there is no restriction in the implementation order of the process at step ST3 and the processes at steps ST4 to ST6. After implementing the process at step ST2, the controller 2 may first implement one of the process at step ST3 and the processes at steps ST4 to ST6, or may implement the processes at the same time.

### Effects

Prevention of Radicals from Flowing In

A conventional substrate processing apparatus does not include the guide mechanism 50 illustrated in the present embodiment. Therefore, the conventional substrate processing apparatus cannot narrow the distance between the front surface of the substrate W and the facing surface of the top board 20 to the limit, to avoid the risk of the substrate W from coming into contact with the top board 20, when the substrate W is lifted and lowered. Hence, it has been difficult to control the distance between the front surface of the substrate W and the facing surface to 0.5 mm or less. Consequently, the radicals supplied from the radical supply port 30 may flow into the center part of the substrate W from the gap 60 between the substrate W and the top board 20, and the film 100 formed on the center part of the substrate W may be etched or peeled off by the radicals that have flowed in.

In contrast, the substrate processing apparatuses 10 and 10A according to the present embodiment include the guide mechanism 50 on the top board 20. Then, the substrate processing apparatuses 10 and 10A can narrow the distance G between the front surface of the substrate W and the facing surface 20a of the top board 20, without the risk of the substrate W coming into contact with the top board 20, by bringing the substrate W into contact with the guide mechanism 50, when the substrate W is lifted and lowered. As a result, the substrate processing apparatuses 10 and 10A can set the lower limit value of the distance G to less than 0.5 mm.

In a state where the distance G is narrowed in this manner, the radicals of etching gas are supplied to the outer peripheral part of the substrate W from the radical supply ports 30. Consequently, the substrate processing apparatuses 10 and 10A can etch the film 100 on the outer peripheral part of the substrate W by the radicals of etching gas, and clean the outer peripheral part of the substrate W. During cleaning, the argon gas supplied through the gas holes 20b passes through the narrow gap 60, and is exhausted to the outer peripheral part from the center part of the substrate. The flow of argon gas prevents radicals from flowing into the gap 60. In this way, it is possible to prevent radicals from flowing into the gap 60. As a result, while the outer peripheral part of the substrate W is cleaned, the substrate processing apparatuses 10 and 10A can prevent the film 100 formed on the center part of the substrate W from being etched or peeled off by radicals. By cleaning the outer peripheral part of the substrate W, in the next process, contamination in the apparatus due to the deposits on the outer peripheral part of the substrate W will be reduced.

### Reduction of Particles

Moreover, by using the buffer member 51, the substrate processing apparatuses 10 and 10A can absorb and buffer the impact caused when the substrate W is brought into contact with the guide mechanism 50. Consequently, the substrate processing apparatuses 10 and 10A can prevent the substrate W from being damaged such as breakage at the contact point of the substrate W. Furthermore, it is possible to reduce particles generated by the impact caused when the substrate W is brought into contact with the guide mechanism 50. Hence, it is possible to prevent contamination in the processing container 1. Still furthermore, the substrate processing apparatuses 10 and 10A cause the contact surface 50a of the guide mechanism 50 to incline according to the shape of the outer peripheral part of the substrate W. Consequently, it is possible to easily absorb and buffer the impact caused when the substrate W is brought into contact with the guide mechanism 50, and easily position the substrate W.

### Reduction of Warpage of Substrate W

Still furthermore, by bringing the outer peripheral part of the substrate W into contact with the guide mechanism 50, the substrate processing apparatuses 10 and 10A can reduce warpage of the substrate W, and make the substrate W flat. As a result, the substrate processing apparatuses 10 and 10A can improve the cleaning accuracy of the outer peripheral part of the substrate W.

### Increase Etching Speed

Still furthermore, the diameter of the stage 11 of the substrate processing apparatus 10A is smaller than the diameter of the substrate W. Consequently, the outer peripheral part of the substrate W is exposed to the outside of the side surface of the stage 11. Therefore, the substrate processing apparatus 10A can clean the outer peripheral part of the substrate W while the substrate W is mounted on the stage 11, without raising the substrate W from the stage 11. Consequently, the temperature of the substrate W will not be reduced during cleaning. As a result, the substrate processing apparatus 10A can increase the etching speed of the outer peripheral part of the substrate W, and reduce the cleaning time of the outer peripheral part of the substrate W.

It should be noted that the embodiments disclosed herein are to be considered as illustrative in all respects and not restrictive, and the above-described embodiments can be embodied in various forms. Moreover, the above embodiments may be omitted, replaced, or modified in various forms without departing from the scope and spirit of the appended claims.

For example, the control method of bringing the substrate W into contact with the contact surface 50a of the guide mechanism 50 is not limited to the method in which the controller 2 controls the support pin 23 to have the height set in advance, by controlling the lifting/lowering mechanism 24. For example, the substrate processing apparatuses 10 and 10A may include a pressure-sensitive element, which is not illustrated, or a piezoelectric element, which is not illustrated, between the top board 20 and the guide mechanism 50. In the substrate processing apparatus 10, the controller 2 may bring the substrate W into contact with the contact surface 50a, by controlling the lifting/lowering mechanism 24 and adjusting the height of the support pin 23, on the basis of the detected value of the pressure-sensitive element or piezoelectric element. Similarly, in the substrate processing apparatus 10A, the controller 2 may bring the substrate W into contact with the contact surface 50a, by controlling the lifting/lowering mechanism 17 and adjusting the height of the stage 11, on the basis of the detected value of the pressure-sensitive element or piezoelectric element.

Moreover, the substrate processing apparatuses 10 and 10A may also include a pressure sensor 52 to detect the contact pressure between the substrate W and the guide mechanism 50, for controlling the lifting/lowering mechanisms 24 and 17. In the substrate processing apparatus 10, the controller 2 may bring the substrate W into contact with the contact surface 50a, by controlling the lifting/lowering mechanism 24 and adjusting the height of the support pin 23, on the basis of the detected value of the pressure sensor 52. Similarly, in the substrate processing apparatus 10A, the controller 2 may bring the substrate W into contact with the contact surface 50a, by controlling the lifting/lowering mechanism 17 and adjusting the height of the stage 11, on the basis of the detected value of the pressure sensor 52.

If the substrate processing apparatuses 10 and 10A have the pressure sensor 52 described above, the controller 2 may determine whether the substrate W is brought into contact with the guide mechanism 50, on the basis of the contact pressure between the substrate W and the guide mechanism 50 detected using the pressure sensor 52. This process is an example of the process (D).

Moreover, the controller 2 may lift/lower the substrate W and/or stop lifting/lowering the substrate W, using the lifting/lowering mechanism 24 or the lifting/lowering mechanism 17, on the basis of the magnitude relation between the detected contact pressure and the threshold value set in advance. This process is an example of the process (C) or the process (E).

For example, the controller 2 may set a first threshold value to be used to control the lifting/lowering speed by the lifting/lowering mechanism 24 or the lifting/lowering mechanism 17, and a second threshold value greater than the first threshold value that is used to control the stop and the lifting/lowering speed by the lifting/lowering mechanism 24 or the lifting/lowering mechanism 17. Then, if the detected contact pressure is greater than the first threshold value and less than the second threshold value, the controller 2 may control the lifting/lowering mechanism 24 or the lifting/lowering mechanism 17 to slow down the lifting/lowering speed of the support pin 23 or the stage 11. Furthermore, if the detected contact pressure is equal to or greater than the second threshold value, the controller 2 may control the lifting/lowering mechanism 24 or the lifting/lowering mechanism 17 to stop lifting or lowering the support pin 23 or the stage 11.

Still furthermore, for example, the controller 2 may not set the first threshold value, but may set in advance the second threshold value that is used to control the stop and the lifting/lowering speed by the lifting/lowering mechanism 24 or the lifting/lowering mechanism 17. Then, if the detected contact pressure is equal to or greater than the second threshold value set in advance, the controller 2 may control the lifting/lowering mechanism 24 or the lifting/lowering mechanism 17 to stop lifting or lowering the support pin 23 or the stage 11.

The substrate processing apparatuses 10 and 10A may include at least one of the lifting/lowering mechanism 24 and the lifting/lowering mechanism 17. The controller 2 may control at least one of the lifting/lowering mechanism 24 and the lifting/lowering mechanism 17 to bring the substrate W into contact with the contact surface 50a.

According to the present disclosure, it is possible to narrow the distance between the substrate and the top board.

Moreover, with respect to the above embodiment,

the following notes are further disclosed.

### Note 1.

A substrate processing apparatus that cleans a substrate, the substrate processing apparatus, comprising:
a processing container;
a stage located inside the processing container and configured to support the substrate;
a top board facing the stage;
a lifting/lowering mechanism configured to lift and lower the substrate; and
a guide mechanism located on the top board and configured to bring the substrate into contact therewith.

### Note 2.

The substrate processing apparatus according to claim 1, wherein
the top board includes a facing surface facing the stage, and
the guide mechanism is configured to adjust distance between a front surface of the substrate and the facing surface of the top board.

### Note 3.

The substrate processing apparatus according to claim 2, wherein
the guide mechanism includes a contact surface protruding from the facing surface and configured to come into contact with the substrate, and
the contact surface is inclined with respect to the facing surface.

### Note 4.

The substrate processing apparatus according to claim 3, wherein
a plurality of the guide mechanisms are arranged at a position of the top board corresponding to an outer peripheral surface of the substrate, and
the plurality of the guide mechanisms bring a plurality of points of the outer peripheral part of the substrate into contact with a plurality of the contact surfaces.

### Note 5.

The substrate processing apparatus according to claim 3, wherein the guide mechanism brings the substrate into surface contact, line contact, or point contact with the contact surface.

### Note 6.

The substrate processing apparatus according to any one of claims 1 to 5, further comprising: a buffer member located between the top board and the guide mechanism and configured to buffer impact caused by contact between the substrate and the guide mechanism.

### Note 7.

The substrate processing apparatus according to claim 6, wherein the buffer member is an elastic member.

### Note 8.

The substrate processing apparatus according to any one of claims 1 to 5, wherein the lifting/lowering mechanism lifts and lowers the substrate by at least one of the stage and a support pin configured to support the substrate.

### Note 9.

The substrate processing apparatus according to any one of claims 1 to 5, wherein
the processing container includes a radical supply port, and
the substrate processing apparatus further comprises a radical supply unit configured to clean the outer peripheral part of the substrate, by supplying a radical of etching gas from the radical supply port.

### Note 10.

The substrate processing apparatus according to claim 9, wherein
the top board includes a facing surface facing the stage, and a gas hole located inside the radical supply port and penetrating through the facing surface, and
the substrate processing apparatus further comprises
a gas supply unit configured to prevent the radical from flowing into a center part of the substrate, by supplying inert gas from the gas hole.

### Note 11.

A substrate processing method executed by a substrate processing apparatus that includes
a processing container including a radical supply port,
a stage located inside the processing container and configured to support a substrate,
a top board including a facing surface facing the stage, and a gas hole located inside the radical supply port and penetrating through the facing surface,
a lifting/lowering mechanism configured to lift and lower the substrate, and
a guide mechanism located on the top board and configured to bring the substrate into contact therewith, the substrate processing method comprising:
(A) preparing the substrate on the stage;
(B) preventing a radical of etching gas from flowing into a center part of the substrate, by supplying inert gas from the gas hole;
(C) lifting and lowering the substrate;
(D) determining contact between the substrate and the guide mechanism;
(E) stopping lifting or lowering the substrate, based on the determined result; and
(F) cleaning an outer peripheral part of the substrate, by supplying the radical of etching gas from the radical supply port.

### Note 12.

The substrate processing method according to claim 11, wherein
at the (D), determines the contact using a pressure sensor configured to detect a contact pressure between the substrate and the guide mechanism, and
at the (E), controls lifting and lowering of the substrate, based on a magnitude relation between the detected contact pressure and a threshold value set in advance.

What is claimed is:

1. A substrate processing apparatus that cleans a substrate, the substrate processing apparatus, comprising:
a processing container;
a stage located inside the processing container and configured to support the substrate;
a top board facing the stage;
a lifting/lowering mechanism configured to lift and lower the substrate; and
a guide mechanism located on the top board and configured to bring the substrate into contact therewith.

2. The substrate processing apparatus according to claim 1, wherein
the top board includes a facing surface facing the stage, and
the guide mechanism is configured to adjust distance between a front surface of the substrate and the facing surface of the top board.

3. The substrate processing apparatus according to claim 2, wherein
the guide mechanism includes a contact surface protruding from the facing surface and configured to come into contact with the substrate, and
the contact surface is inclined with respect to the facing surface.

4. The substrate processing apparatus according to claim 3, wherein
a plurality of the guide mechanisms are arranged at a position of the top board corresponding to an outer peripheral surface of the substrate, and
the plurality of the guide mechanisms bring a plurality of points of the outer peripheral part of the substrate into contact with a plurality of the contact surfaces.

5. The substrate processing apparatus according to claim 3, wherein the guide mechanism brings the substrate into surface contact, line contact, or point contact with the contact surface.

6. The substrate processing apparatus according to claim 1, further comprising: a buffer member located between the top board and the guide mechanism and configured to buffer impact caused by contact between the substrate and the guide mechanism.

7. The substrate processing apparatus according to claim 6, wherein the buffer member is an elastic member.

8. The substrate processing apparatus according to claim 1, wherein the lifting/lowering mechanism lifts and lowers the substrate by at least one of the stage and a support pin configured to support the substrate.

9. The substrate processing apparatus according to claim 1, wherein
the processing container includes a radical supply port, and
the substrate processing apparatus further comprises a radical supply unit configured to clean the outer peripheral part of the substrate, by supplying a radical of etching gas from the radical supply port.

10. The substrate processing apparatus according to claim 9, wherein
the top board includes a facing surface facing the stage, and a gas hole located inside the radical supply port and penetrating through the facing surface, and
the substrate processing apparatus further comprises
a gas supply unit configured to prevent the radical from flowing into a center part of the substrate, by supplying inert gas from the gas hole.

11. A substrate processing method executed by a substrate processing apparatus that includes
a processing container including a radical supply port,
a stage located inside the processing container and configured to support a substrate,
a top board including a facing surface facing the stage, and a gas hole located inside the radical supply port and penetrating through the facing surface,
a lifting/lowering mechanism configured to lift and lower the substrate, and
a guide mechanism located on the top board and configured to bring the substrate into contact therewith, the substrate processing method comprising:
(A) preparing the substrate on the stage;
(B) preventing a radical of etching gas from flowing into a center part of the substrate, by supplying inert gas from the gas hole;
(C) lifting and lowering the substrate;
(D) determining contact between the substrate and the guide mechanism;
(E) stopping lifting or lowering the substrate, based on the determined result; and
(F) cleaning an outer peripheral part of the substrate, by supplying the radical of etching gas from the radical supply port.

12. The substrate processing method according to claim 11, wherein
at the (D), determines the contact using a pressure sensor configured to detect a contact pressure between the substrate and the guide mechanism, and
at the (E), controls lifting and lowering of the substrate, based on a magnitude relation between the detected contact pressure and a threshold value set in advance.
